(19) United States
(12) Patent Application Publication
(10) Pub. No.: US 2011/0198983 A1
(43) Pub. Date: Aug. 18, 2011

(54) COMPOSITE PRODUCED FROM INTERMETALLIC PHASES AND METAL

(75) Inventors: Harald Manhardt, Bruchkobel (DE); David Francis Lupton, Gelnhausen (DE); Tanja Eckardt, Dreieich (DE); Holger Zingg, Biebergemund (DE)

(73) Assignee: W.C. HERAEUS GMBH, Hanau (DE)

(21) Appl. No.: 12/295,360

(22) PCT Filed: Mar. 29, 2007
(86) PCT No.: PCT/EP2007/002812

§ 371 Date: Oct. 12, 2010

(30) Foreign Application Priority Data
Mar. 30, 2006 (DE) 10 2006 015 167.4

(51) Int. Cl. H01J 19/42; H01J 37/305; B32B 15/01; B32B 15/02; B22F 1/00; B22F 7/00; B22F 3/02; B22F 3/12

(52) U.S. Cl. 313/252; 428/548; 419/62; 419/8; 75/230

(57) ABSTRACT

A method is provided for producing a wire or tape, especially for use as an electrode or electrode tip in spark plugs. The method includes the following steps: (a) producing an intermetallic compound having a melting point above 1700° C.; (b) grinding the intermetallic compound; (c) mixing the intermetallic compound with metal powder; (d) introducing the mixture obtained in step (c) in a tube produced from ductile material; and (e) shaping the tube filled in step (d) to give a wire or tape. Also provided are a wrapped wire or wrapped tape, especially a semifinished product for producing electrodes or electrode tips of spark plugs.

### CROSS-REFERENCE TO RELATED APPLICATIONS

This application is a Section 371 of International Application No. PCT/EP2007/002812, filed Mar. 29, 2007, which was published in the German language on Oct. 11, 2007, under International Publication No. WO 2007/112936 A2 and the disclosure of which is incorporated herein by reference.

### BACKGROUND OF THE INVENTION

The present invention relates to a semifinished product and its production, particularly for use in spark plugs, as an electrode, electrode tip, support, or inlay.

Many attempts have been made to provide erosion-resistant materials as an alternative to platinum for electrodes or electrode tips in spark plugs. Ceramic additives, however, reduce the conductivity and lead to increased brittleness of the semifinished product. Metallic variants lead to easier oxidation, accompanied by the formation of cracks.

It is also known that intermetallic compounds are often hard and also rather chemically resistant. An intermetallic compound or intermetallic phase is a compound made of two or more metals. In contrast to alloys, they exhibit lattice structures that differ from that of the constituent metals. In a narrow sense, the composition of an intermetallic phase is fixed stoichiometrically corresponding to a fixed mixture ratio. In a broader sense, the intermetallic phase can be varied around the stoichiometric composition within a more or less wide homogeneity range. The special physical and mechanical properties of such compounds result from the especially strong bond between the unequal atoms, with this bond being predominantly metallic with larger or smaller proportions of other bond types. Intermetallic phases with the desired high-temperature resistance contrast to difficult processability due to high brittleness. Intermetallic phases assume an intermediate position between metallic alloys and ceramics. Intermetallic phases are produced by both powder metallurgical and also conventional melting processes, wherein production and processing can be difficult due to their mechanical properties. Therefore, the spread of intermetallic phases to industrial mass production has been very limited.

The production of wire-shaped or tape-shaped semifinished products made of intermetallic phases for automated further processing as spark plug parts is desirable. Flexible wires or tapes that can be wound up and that are made of intermetallic phases are not known.

German published patent application DE 30 30 847 A1 discloses a compound material for spark plugs made of a core of ruthenium or iridium or alloys thereof, wherein this material is dispersed in a matrix metal made of silver or copper or gold or palladium or nickel or corresponding alloys or mixtures thereof. A jacket surrounding this core is made of nickel or nickel alloys. For this purpose, a rod made of powder of the core material is pressed and placed in a tube made of nickel or a nickel alloy, whereupon the tube ends are closed and the tube diameter is deformed by cold deformation to the desired outer diameter.

### BRIEF SUMMARY OF THE INVENTION

The object of the present invention comprises providing a semifinished product in the form of a wire or tape that can be fed continuously and that is suitable for an automated, economical production of spark plugs and is competitive with platinum in its properties with respect to erosion resistance and electrical conductivity.

The object is achieved by a method for the production of a wire or tape, in particular for the use as an electrode or electrode tube in spark plugs, in which the following steps are performed:
a) generating an intermetallic compound having a melting point greater than 1700° C.;
b) grinding the intermetallic compound;
c) mixing the intermetallic compound with metal powder;
d) introducing the mixture obtained under c) into a tube made of ductile material; and
e) transforming the tube filled according to d) to a wire or tape.
   The object is further achieved by a sheathed or unsheathed (sheath-free) wire or tape, preferably a semifinished product for the production of electrodes or electrode tips of spark plugs, wherein the wire sheath or the tape sheath contains a compressed mixture of an intermetallic compound with a noble metal powder

According to the invention, an intermetallic compound having a melting point greater than 1700° C., preferably RuAl, is mixed with another metal, preferably Pt, wherein this mixture is transformed in a tube made of a ductile material into a wire or tape-shaped compound material. For the production of intermetallic phases, melting or sintering methods are suitable. Production with an electric arc has proven especially effective. For mixing with another metal, grinding of the intermetallic phases is suitable for mixing with another metal powder, in particular platinum powder or Pt—Ir alloy. Such a powder mixture is transformed in a tube made of a ductile material, e.g., platinum, stainless steel, or nickel. It has proven effective to seal the tube after filling the powder mixture under a vacuum and to perform a preliminary compression, for example by hammering. It has also proven effective to first press the powder mixture into a cylinder, preferably by isostatic cold pressing and then to push the cylinder into a jacket tube. The compound is then likewise preferably further compressed, in order to then be transformed into wire or tape.

The known wire drawing processes are suitable for drawing a wire. The wire that can be further processed as a semifinished product is preferably wound up before its intended use as electrodes or electrode tips. The electrodes or electrode tips can then be produced in a known way, for example by stamping, when the wire is unwound.

It has proven effective furthermore to roll a wire into a tape, which can be processed analogously to inlays for spark plugs. The transformation of the filled tube is not limited to wire drawing processes. For example, the tube can also be transformed through rolling. Preferably, the wire or the tape is further hardened by sintering before being wound up. The typical diameter of the wire used as the semifinished product equals 0.1 to 2 mm, in particular 0.6 to 1 mm.

The volume percentage of the intermetallic phase in the mixture with the other metal equals between 5 and 50 vol. %, preferably 10 to 30 vol. %. Suitable intermetallic compounds AₓB_{y} contain for A an element from the group Ru, Ir, Pt, Rh, or Pd and for B an element from the group

Zr, Al, Y, Hf, Th, Ti, Ta, Sc, V, Nb, Ce, W, or lanthanides, wherein the ratio x:y lies between 0.8 and 5. The mixture can contain different intermetallic compounds, in particular when these accumulate next to each other during production, for example Ru₂Al₃ next to RuAl. The metal in the mixture can be a pure metal, such as platinum, an alloy, such as PtIrl, or a mixture of two metals, such as platinum and platinum-iridium alloy. The decisive factor is that at least one metal and one intermetallic phase are mixed with each other and are shaped into a structure. An especially preferred intermetallic compound is RuAl and a preferred additional metal is platinum. In a metal matrix, intermetallic phases orient themselves parallel to the axis of the wire or tape during the processing according to the invention to form wire or tape. This structure with preferred direction of the embedded phase guarantees an especially high flexibility of the semifinished product as well as a minimal erosion with the intended application.

The compound material according to the invention is suitable as a semifinished product for further processing into parts for spark plugs, such as electrodes, electrode tips, supports, or inlays. The tips can be connected to the base electrode by known joining methods, in particular by welding, soldering, or sintering. Further fields of use for the semifinished product according to the invention are switch contacts or slide contacts, in which high currents lead to discharge or erosion processes in the contact region. Furthermore, the semifinished product can be used as a current feedthrough in high-power discharge lamps, where high thermal and corrosive stresses exist with simultaneous current transmission, so that the advantages of the material according to the invention are best utilized. In comparison to pure platinum electrodes, through the addition of an intermetallic phase, which is made of at least one non-noble (base) metal component, the total content of precious and cost-intensive noble metals is reduced, without losing performance.

The mixtures according to the invention made of intermetallic phases and metals can be modified by additional ceramic or metallic additives, for example by oxidation of the base metal, which is optionally present in excess in the intermetallic phase.

In further inventive embodiment, the material of the tube, which is transformed during the wire production into the wire sheath, is removed again, in particular with acid. In this way, a stripped wire can be provided, which still has only minimal impurities of the prior sheath. With this method, precious tube material, in particular platinum, can be saved.

In another preferred embodiment, tubes used according to the invention are closed on one end. These tubes constructed as containers allow easier filling of the tubes.

The sheathed or stripped wires or tapes according to the invention are cut into small sections before their use as spark plug tips. In this way, especially resistant electrode tips are produced in a simple way and while saving noble metal.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a simplified longitudinal perspective view of a platinum sheathing tube filled with a powder mixture of Pt and RuAl according to an embodiment of the invention;

FIG. 2 is a simplified side view of the tip of a spark plug center electrode arranged on a base electrode; and

FIG. 3 is a schematic diagram of the structure of a material compound according to an embodiment of the invention.

### DETAILED DESCRIPTION OF THE INVENTION

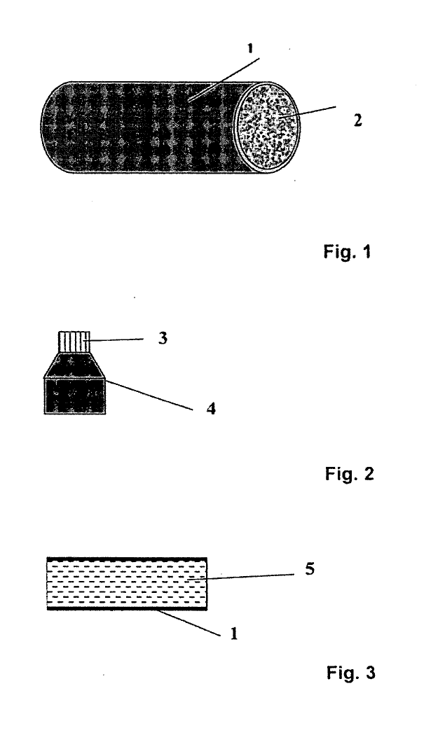

The sheathing tube 1 according to FIGS. 1 and 3 is a ductile sleeve 1, for example made of stainless steel, ferritic steel, nickel, platinum, gold, niobium, or platinum-iridium alloy. Its tensile strength is greater than 150 MPa, preferably at least 250 MPa. Its elongation is >10%, preferably greater than 15%. A tube according to FIGS. 1 and 3 to be drawn into a wire is cut into disks or tubular pieces 2, in order to be used according to FIG. 2 on a base electrode 4 made of platinum or nickel alloy as a tip 2 of a spark plug center electrode. According to FIGS. 1 and 3, intermetallic phases are arranged in a matrix made of metal. The intermetallic phase is here according to FIG. 3 oriented in a preferred direction 5 parallel to the wire length. In this way, the flexibility of the semifinished product is significantly improved, wherein minimal erosion is maintained for the intended use.

### Example 1

As starting materials, 80 wt. % Ru and 20 wt. % Al were melted under a vacuum by an electric arc. The resulting granulate was ground in a vibrating disk mill. The X-ray diffraction analysis gave the intermetallic phase RuA1 as the main phase. This powder was homogenized with platinum powder (grain size <63 μm) in a ratio of 20 vol. % RuAl and 80 vol. % Pt in a tumbling mixer. Then, the powder was filled into a Pt tube having an outer diameter of 7 mm and a wall thickness of 1 mm. The open ends of the tube were closed under vacuum. The tube was hammered to 3 mm in a rotary swaging machine and sealed. Then, the wire drawing process followed up to the final diameter.

### Example 2

Analogous to Example 1, an intermetallic phase was produced from 80 wt. % Ru and 20 wt.% Al, homogenized with 80 vol. % Pt (20 vol. % RuAl) in a tumbling mixer, and filled into a PtIr10 tube with a 7 mm diameter and a 1 mm wall thickness. The tube was drawn to the final diameter.

### Example 3

Analogous to Example 1, a PtIr10 tube was filled with a homogenized powder mixture made of 80 vol. % Pt (20 vol. % RuAl) and closed under a vacuum, then the tube was hammered to 3 mm at about 700° C. on a rotary swaging machine and drawn to the final dimensions.

### Example 4

Analogous to Example 1, a nickel tube was filled with a homogenized powder mixture made of 80 vol. % Pt (20 vol. % RuAl) and closed under a vacuum, then the tube was drawn to its final diameter.

### Example 5

Analogous to Example 1, a mixture was produced from 48 wt. % Ru and 52 wt. % Zr and homogenized with Pt in a ratio of 80 vol. % Pt and 20 vol. % RuZr in a tumbling mixer; then, analogous to Example 1, it was hammered to 3 mm and drawn to its final dimensions.

### Example 6

Analogous to Example 1, a mixture was produced from 65 wt. % Ru and 35 wt. % Hf and homogenized with Pt in a ratio of 80 vol. % Pt and 20 vol. % RuHf in a tumbling mixer; then, analogous to Example 1, it was hammered to 3 mm and drawn to its final dimensions.

### Example 7

Analogous to Example 1, a mixture was produced from 80 wt. % Ru and 20 wt. % Al.

The powder was homogenized with Pt in a ratio of 70 vol. % Pt and 30 vol. % RuAl in a tumbling mixer and filled into a PtIr10 tube. The tube was hammered to 3 mm at about 700° C. on a rotary swaging machine and then drawn to its final dimensions.

### Example 8

Analogous to Example 1, a mixture was produced from 80 wt. % Ru and 20 wt. % Al. With Pt in a ratio of 70 vol. % Pt and 30 vol. % RuAl, the powder was homogenized in a tumbling mixer and filled in several Pt tubes. The tubes were hammered to 3 mm on a rotary swaging machine. These tubes were cut into 400 mm long sections, and these were positioned in a steel tube having an outer diameter of 24 mm with a wall thickness of 3 mm, so that a tight packing was produced. This tube was hammered to 7 mm on a rotary swaging machine and drawn to its final dimensions.

### Example 9

Analogous to Example 1, an intermetallic phase was produced from 80 wt. % Ru and 20 wt. % Al and homogenized with Pt in a ratio of 20 vol. % RuAl and 80 vol. % Pt in a tumbling mixer. Then, the powder was filled into a stainless steel tube having an outer diameter of 8 mm and a wall thickness of 1.1 mm. The tube was evacuated, closed, and hammered to 3 mm at about 700° C. on a rotary swaging machine, and sealed. By wire drawing the diameter was reduced to 1.5 mm. The tube was then removed by etching in 50 percent HCl at about 50° C. and the wire was further drawn to a diameter of 0.7 mm.

### Example 10

Analogous to Example 1, a mixture was produced from 20 vol. % RuAl and 80 vol. % Pt and filled into a cylindrical container closed on one end and made of stainless steel having an outer diameter of 40 mm, a length of 80 mm, and a wall thickness of 1.5 mm. The open end of the container was closed by welding by a stainless steel disk with suction port. Via the port, the container was evacuated and the port was then quenched and welded. The container was heated to 700° C., pre-compressed in the closed receiver of an extruding press with a force of 250 tons and then extruded through a mold to form a rod having a diameter of 16 mm. The rod was hammered to 3 mm at about 500° C. on a rotary swaging machine. By wire drawing the diameter was reduced to 1.5 mm. The tube was then removed by etching in 50 percent HCl at about 50° C. and the wire was further drawn to a diameter of 0.7 mm.

### Example 11

A wire produced according to Examples 1 to 10 is rolled into a tape.

### Example 12

A wire produced according to Examples 1 to 10 or a tape produced according to Example 11 is cut into small sections, which are used as electrode tips of spark plugs.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-23. (canceled)

24. A method for production of a wire or tape, the method comprising performing the following steps:
a) generating an intermetallic compound having a melting point greater than 1700° C., the compound containing at least one element from the group Ru, Ir, Pt, Rh, and Pd;
b) grinding the intermetallic compound;
c) mixing the intermetallic compound with metal powder;
d) introducing the mixture obtained in step (c) into a tube made of ductile material; and
e) transforming the tube filled according to step (d) to a wire or tape.

25. The method according to claim 24, wherein the tube made of ductile material is closed after filling of the mixture of the intermetallic compound and the metal powder.

26. The method according to claim 25, wherein the filled and closed tube is pre-compressed.

27. The method according to claim 25, wherein the filled and closed tube is pre-compressed.

28. The method according to claim 24, wherein the wire or the tape is sintered.

29. The method according to claim 24, wherein the wire or the tape is wound up.

30. The method according to claim 24, wherein the intermetallic compound is generated in an electric arc.

31. The method according to claim 24, wherein the ground intermetallic compound is mixed with platinum powder.

32. The method according to claim 24, wherein the intermetallic compound is RuAl.

33. The method according to claim 24, wherein the tube made of ductile material comprises platinum, stainless steel, or nickel

34. The method according to claim 24, wherein any tube material remaining on the wire is removed.

35. A sheathed wire or sheathed tape, comprising a sheath containing a compressed mixture of an intermetallic compound with a noble metal powder, wherein a volume proportion of the intermetallic compound in the mixture equals between 5 and 50 vol.-%.

36. The sheathed wire or sheathed tape according to claim 35, wherein the intermetallic compound corresponds to formula AₓB_{y}, wherein A is selected from the group Ru, Ir, Pt, Rh, and Pd, and B is selected from the group Zr, Al, Y, Hf, Th, Ti, Ta, Sc, V, Nb, Ce, W, and the lanthanides, and the ratio x:y lies between 0.8 and 5.

37. The sheathed wire or sheathed tape according to claim 35, wherein the mixture in the sheath contains platinum.

38. The sheathed wire or sheathed tape according to claim 35, wherein the sheath comprises platinum.

39. A sheathing-free wire or sheathing-free tape comprising a compressed mixture of an intermetallic compound with a noble metal powder.

40. The sheathed wire or sheathed tape according to claim 35, wherein the wire or tape is a component of a spark plug.

41. The sheathed wire or sheathed tape according to claim 40, wherein the component is an electrode, electrode tip, support, or inlay in a spark plug.

42. The sheathed wire or sheathed tape according to claim 35, wherein the wire or tape is a switch contact, slide contact, or current feedthrough.

43. The sheathed wire or sheathed tape according to claim 42, wherein high currents lead to discharge or erosion processes in a contact region.

44. The sheathed wire or sheathed tape according to claim 42, wherein high thermal and corrosive loadings are present for simultaneous current transmission.

45. An electrode tip of a spark plug, wherein the tip comprises a sheathed or stripped, compressed mixture of an intermetallic compound with a noble metal powder.

46. The electrode tip according to claim 45, wherein the tip includes impurities originating from a stripped sheath.
